(19) United States
(12) Patent Application Publication
(10) Pub. No.: US 2025/0081652 A1
(43) Pub. Date: Mar. 6, 2025

(54) IMAGE SENSING DEVICE

(71) Applicant: SK hynix Inc., Icheon-si (KR)

(72) Inventor: Sang Jin PARK, Icheon-si (KR)

(21) Appl. No.: 18/615,850

(22) Filed: Mar. 25, 2024

(30) Foreign Application Priority Data
Aug. 29, 2023 (KR) 10-2023-0113576

(51) Int. Cl. H01L 27/146

(52) U.S. Cl. CPC H10F 39/807; H10F 39/802; H10F 39/811

(57) ABSTRACT

An image sensing device includes a semiconductor substrate; unit pixels supported by the semiconductor substrate to detect light incident to the unit pixels and to convert detected light into pixel signal, and an inter-pixel isolation structure disposed between adjacent unit pixels to physically isolate the adjacent unit pixel from each other. Each unit pixel includes photoelectric conversion elements, an inner-pixel isolation structure disposed between adjacent photoelectric conversion elements within the unit pixel and at least one overflow path configured to interconnect the photoelectric conversion elements within the unit pixel, and wherein each unit pixel is shaped in a triangular shape when viewed in a plane.

### CROSS-REFERENCE TO RELATED APPLICATION

This patent document claims the priority and benefits of Korean patent application No. 10-2023-0113576, filed on Aug. 29, 2023, which is incorporated by reference in its entirety as part of the disclosure of this patent document.

### TECHNICAL FIELD

The technology and implementations disclosed in this patent document generally relate to an image sensing device having a triangular pixel structure.

### BACKGROUND

An image sensor is used in electronic devices to convert optical images into electrical signals. With the recent development of automotive, medical, computer and communication industries, the demand for highly integrated, higher-performance image sensors has been rapidly increasing in various electronic devices such as digital cameras, camcorders, personal communication systems (PCSs), video game consoles, surveillance cameras, medical micro-cameras, robots, etc.

The CCD image sensing device may be driven more easily than the CCD sensing device. The CMOS image sensing device enables conventional circuits to be integrated into a single chip, such that the CMOS image sensing device can be easily fabricated as a small-sized product, and has a higher degree of integration and very lower power consumption. In addition, the CMOS image sensing device is compatible with CMOS fabrication technology, resulting in reduction in production costs. In recent times, the CMOS image sensing devices have been intensively researched and rapidly come into widespread use.

In addition, the image sensing device includes a phase-difference detection autofocus (PDAF) function that automatically focuses by detecting a phase difference between adjacent pixels.

### SUMMARY

Various embodiments of the disclosed technology relate to an image sensing device capable of improving phase-difference detection characteristics while minimizing image distortion.

In accordance with an embodiment of the disclosed technology, an image sensing device may include a semiconductor substrate; unit pixels supported by the semiconductor substrate to detect light incident to the unit pixels and to convert detected light into pixel signals, respectively; and an inter-pixel isolation structure disposed between adjacent unit pixels to physically isolate the adjacent unit pixels from each other. Each unit pixel may include (1) photoelectric conversion elements producing photocharge for generation of a pixel signal of each unit pixel in response to incident light detected by the unit pixel, (2) an inner-pixel isolation structure disposed between adjacent photoelectric conversion elements within the unit pixel and (3) at least one overflow path configured to interconnect the photoelectric conversion elements within the unit pixel, and wherein each unit pixels is shaped in a triangular shape when viewed in a plane.

In accordance with another embodiment of the disclosed technology, an image sensing device may include a plurality of unit pixels consecutively arranged in a first direction and a second direction intersecting the first direction, each unit pixel exhibiting a triangular shape when viewed in a plane and configured to produce photocharge in response to incident light; and a first isolation structure disposed between adjacent unit pixels and configured to isolate the adjacent unit pixels from each other. Each of the plurality of unit pixels may include a first photoelectric conversion element that converts light into photocharge; a second photoelectric conversion element that converts light into photocharge and is disposed adjacent to the first photoelectric conversion element in a first diagonal direction; and a third photoelectric conversion element that converts light into photocharge and is disposed adjacent to the first photoelectric conversion element in a second diagonal direction intersecting the first diagonal direction, and disposed adjacent to the second photoelectric conversion element in a first direction intersecting the first diagonal direction and the second diagonal direction.

In accordance with another embodiment of the disclosed technology, an image sensing device may include a semiconductor substrate; an inter-pixel isolation structure disposed between adjacent unit pixels within the semiconductor substrate; a plurality of photoelectric conversion elements disposed in the unit pixels within the semiconductor substrate, respectively; an inner-pixel isolation structure disposed between adjacent photoelectric conversion elements within the unit pixel; and at least one overflow path formed to interconnect the photoelectric conversion elements within the unit pixel, and wherein each of the unit pixels is formed in a triangular shape when viewed in a plane.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some implementations of the disclosed technology.

FIG. 2 is a schematic diagram illustrating an example of a planar structure of a unit pixel based on some implementations of the disclosed technology.

FIG. 3 is a schematic diagram illustrating an example of an arrangement shape in which the unit pixels shown in FIG. 2 are arranged in an array shape based on some implementations of the disclosed technology.

FIG. 4A is a cross-sectional view illustrating an example of a pixel structure taken along the line XY-XY′ shown in FIG. 2 based on an embodiment of the disclosed technology, and FIG. 4B is a cross-sectional view illustrating an example of a pixel structure taken along the line X-X′ shown in FIG. 2 based on an embodiment of the disclosed technology.

FIG. 5A is a cross-sectional view illustrating an example of a pixel structure taken along the line XY-XY′ shown in FIG. 2 based on another embodiment of the disclosed technology, and FIG. 5B is a cross-sectional view illustrating an example of a pixel structure taken along the line X-X′ shown in FIG. 2 based on another embodiment of the disclosed technology.

FIGS. 6A and 6B are schematic diagrams illustrating examples of inner-pixel isolation structures based on another embodiment of the disclosed technology.

FIG. 7 is a cross-sectional view illustrating an example of a pixel structure taken along the line X-X′ shown in FIGS. 6A and 6B based on an embodiment of the disclosed technology.

FIG. 8 is a cross-sectional view illustrating an example of a pixel structure taken along the line X-X′ shown in FIGS. 6A and 6B based on another embodiment of the disclosed technology.

FIG. 9 is a schematic diagram illustrating examples of planar structures of a unit pixel based on another embodiment of the disclosed technology.

FIG. 10 is a schematic diagram illustrating an example of a planar structure of a unit pixel based on another embodiment of the disclosed technology.

### DETAILED DESCRIPTION

This patent document provides implementations and examples of an image sensing device having a triangular pixel structure that may be used to substantially address one or more technical or engineering issues and mitigate limitations or disadvantages encountered in some other image sensing devices. Some implementations of the disclosed technology suggest examples of an image sensing device capable of improving phase-difference detection characteristics while minimizing image distortion. The disclosed technology provides various implementations of the image sensing device that can improve phase-difference detection characteristics while minimizing image distortion by improving a pixel structure.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

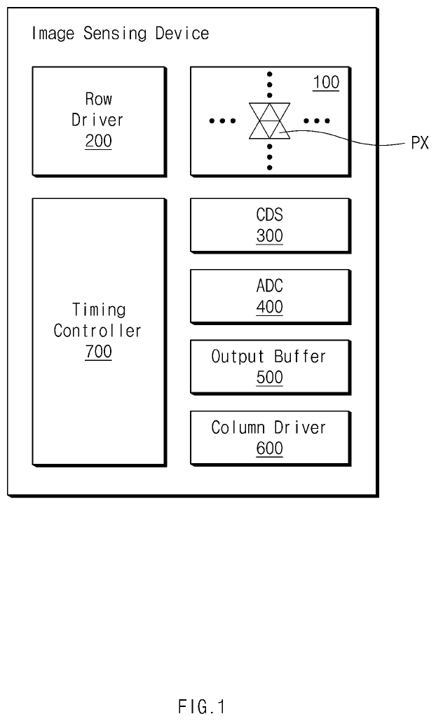

FIG. 1 is a block diagram illustrating an example of an image sensing device based on some implementations of the disclosed technology.

Referring to FIG. 1, the image sensing device may include a pixel array 100, a row driver 200, a correlated double sampler (CDS) 300, an analog-digital converter (ADC) 400, an output buffer 500, a column driver 600 and a timing controller 700. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light, and a phase detection pixel that is structured to generate second electrical signals for calculating a phase difference between the images.

The pixel array 100 may include a plurality of unit pixels (PXs) arranged in rows and columns. In one example, the plurality of unit pixels (PXs) can be arranged in a two dimensional (2D) pixel array including rows and columns. In another example, the plurality of unit pixels (PXs) can be arranged in a three dimensional (3D) pixel array. The plurality of unit pixels (PXs) may convert an optical signal into an electrical signal on a unit pixel basis or a pixel group basis, where unit pixels in a pixel group share at least certain internal circuitry. Electrical signals generated from the unit pixels (PXs) may be used as image signals to generate an image corresponding to a target object to be captured, and may also be used as a phase-difference detection signal for an autofocus operation. Each of the unit pixels (PXs) may be formed in a triangular shape when viewed in a plane, and each unit pixel (PX) may include a plurality of photoelectric conversion elements. Each unit pixel (PX) may generate and output a plurality of electrical signals corresponding to photocharges generated by each of the plurality of photoelectric conversion elements. A more detailed structure of each unit pixel (PX) will be described later.

The pixel array 100 may receive driving signals (for example, a row selection signal, a reset signal, a transmission (or transfer) signal, etc.) from the row driver 200. Upon receiving the driving signal, the unit pixels may be activated to perform the operations corresponding to the row selection signal, the reset signal, and the transfer signal.

The row driver 200 may activate the pixel array 100 to perform certain operations on the unit pixels in the corresponding row based on control signals provided by controller circuitry such as the timing controller 700. In some implementations, the row driver 200 may select one or more pixel groups arranged in one or more rows of the pixel array 100. The row driver 200 may generate a row selection signal to select one or more rows from among the plurality of rows. The row driver 200 may sequentially enable the reset signal and the transfer signal for the unit pixels arranged in the selected row. The pixel signals generated by the unit pixels arranged in the selected row may be output to the correlated double sampler (CDS) 300.

The correlated double sampler (CDS) 300 may remove undesired offset values of the unit pixels using correlated double sampling. In one example, the correlated double sampler (CDS) 300 may remove the undesired offset values of the unit pixels by comparing output voltages of pixel signals (of the unit pixels) obtained before and after photocharges generated by incident light are accumulated in the sensing node (i.e., a floating diffusion (FD) node). As a result, the CDS 300 may obtain a pixel signal generated only by the incident light without causing noise. In some implementations, upon receiving a clock signal from the timing controller 700, the CDS 300 may sequentially sample and hold voltage levels of the reference signal and the pixel signal, which are provided to each of a plurality of column lines from the pixel array 100. That is, the CDS 300 may sample and hold the voltage levels of the reference signal and the pixel signal which correspond to each of the columns of the pixel array 100. In some implementations, the CDS 300 may transfer the reference signal and the pixel signal of each of the columns as a correlate double sampling (CDS) signal to the ADC 400 based on control signals from the timing controller 700.

The ADC 400 is used to convert analog CDS signals received from the CDS 300 into digital signals. In some implementations, the ADC 400 may be implemented as a ramp-compare type ADC. The analog-to-digital converter (ADC) 400 may compare a ramp signal received from the timing controller 700 with the CDS signal received from the CDS 300, and may thus output a comparison signal indicating the result of comparison between the ramp signal and the CDS signal. The analog-to-digital converter (ADC) 400 may count a level transition time of the comparison signal in response to the ramp signal received from the timing controller 700, and may output a count value indicating the counted level transition time to the output buffer 500.

The output buffer 500 may temporarily store column-based image data provided from the ADC 400 based on control signals of the timing controller 700. The image data received from the ADC 400 may be temporarily stored in the output buffer 500 based on control signals of the timing controller 700. The output buffer 500 may provide an interface to compensate for data rate differences or transmission rate differences between the image sensing device and other devices.

The column driver 600 may select a column of the output buffer 500 upon receiving a control signal from the timing controller 700, and sequentially output the image data, which are temporarily stored in the selected column of the output buffer 500. In some implementations, upon receiving an address signal from the timing controller 700, the column driver 600 may generate a column selection signal based on the address signal, may select a column of the output buffer 500 using the column selection signal, and may control the image data received from the selected column of the output buffer 500 to be output as an output signal.

The timing controller 700 may generate signals for controlling operations of the row driver 200, the ADC 400, the output buffer 500 and the column driver 600. The timing controller 700 may provide the row driver 200, the column driver 600, the ADC 400, and the output buffer 500 with a clock signal required for the operations of the respective components of the image sensing device, a control signal for timing control, and address signals for selecting a row or column.

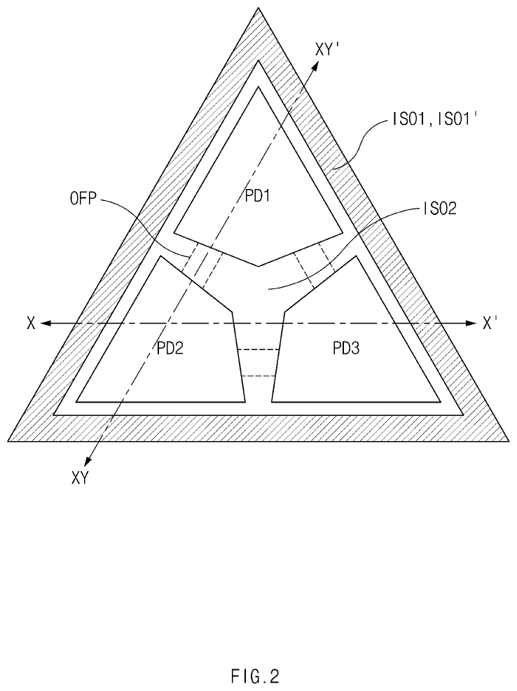

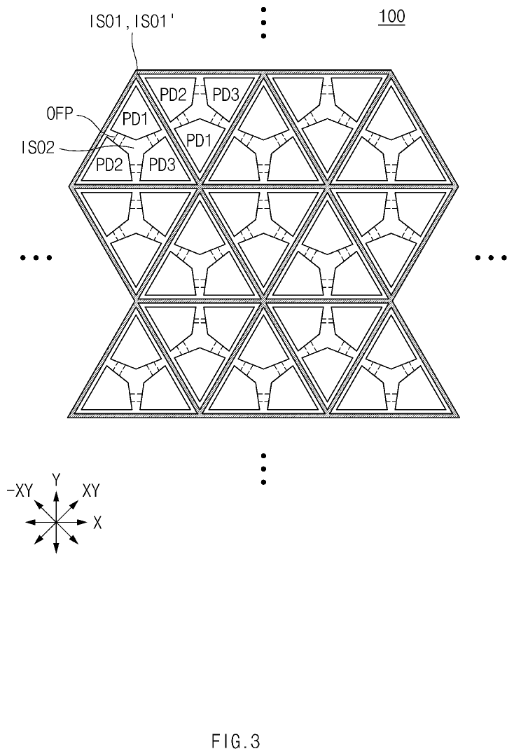

FIG. 2 is a schematic diagram illustrating an example of a planar structure of a unit pixel based on some implementations of the disclosed technology. FIG. 3 is a schematic diagram illustrating an example of an arrangement of the unit pixels shown in FIG. 2 based on some implementations of the disclosed technology.

Referring to FIGS. 2 and 3, a pixel array 100 may include a plurality of unit pixels (PXs) consecutively arranged in a first direction (e.g., an X-axis direction) and a second direction (e.g., a Y-axis direction) perpendicular to the first direction. Each unit pixel (PX) may be formed in a triangular shape when viewed in a plane. Thus, a plan view of each unit pixel (PX) has a triangular shape. In some implementations, each unit pixel (PX) may be formed in an equilateral triangle shape with three sides having the same length.

In the pixel array 100, the unit pixels located adjacent to each other in the first or second direction may be symmetrical to each other with respect to a reference line between the unit pixels. For example, in the pixel array 100, when the first unit pixel having three sides and the second unit pixel having three sides are arranged to be adjacent each other in the first direction (e.g., X direction) or the second direction (e.g., Y direction), the first unit pixel and the second unit pixel shares one common side and the first unit pixel and the second unit pixel are placed symmetrical with respect to the common side. In this case, one of the first unit pixel and the second unit pixel is arranged to have an inverted shape of the other one of the first unit pixel and the second unit pixel.

The unit pixel (PX) may include a plurality of photoelectric conversion elements (PD1˜PD3). In some implementations, three photoelectric conversion elements (PD1˜PD3) may be respectively located at the corner regions in one-to-one correspondence with three corners of each triangle. Each of the photoelectric conversion elements (PD1˜PD3) may include N-type impurities, and may generate photocharges through photoelectric conversion of incident light.

The unit pixel (PX) may output three sub-pixel signals respectively corresponding to the three photoelectric conversion elements (PD1˜PD3). For example, each unit pixel PX may output a first sub-pixel signal corresponding to photocharges generated by the photoelectric conversion element PD1, a second sub-pixel signal corresponding to photocharges generated by the photoelectric conversion element PD2, and a third sub-pixel signal corresponding to photocharges generated by the photoelectric conversion element PD3.

The first to third sub-pixel signals may be used as image signals to generate an image corresponding to the target object to be captured. For example, for each unit pixel (PX), the first to third sub-pixel signals may be summed to create one pixel signal (i.e., an image signal) for the corresponding unit pixel (PX). The unit pixels (PXs) may include a red pixel formed to generate an image signal corresponding to light of a red color, a green pixel formed to generate an image signal corresponding to light of a green color, and a blue pixel formed to generate an image signal corresponding to light of a blue color. In some implementations, red pixels, green pixels, and blue pixels may be arranged in a Bayer pattern.

In some implementations, the first to third sub-pixel signals may be used as a phase detection signal for an autofocus operation. In the unit pixel (PX), the sub-pixel signals of two adjacent photoelectric conversion elements (e.g., PD1 and PD2, PD1 and PD3, PD2 and PD3) may be compared with each other, so that a phase difference in a neighboring direction of the two adjacent photoelectric conversion elements can be detected. For example, the first sub-pixel signal of the photoelectric conversion element PD1 and the second sub-pixel signal of the photoelectric conversion element PD2 may be compared with each other, so that a phase difference in a first diagonal direction (e.g., a direction of PD1↔PD2 that is shown as XY direction in FIG. 3) can be detected. Since the first sub-pixel signal of the photoelectric conversion element PD1 and the third sub-pixel signal of the photoelectric conversion element PD3 are compared with each other, a phase difference in a second diagonal direction (e.g., a direction of PD1↔PD3 that is shown as −XY direction in FIG. 3) can be detected. In addition, since the second sub-pixel signal of the photoelectric conversion element PD2 and the third sub-pixel signal of the photoelectric conversion element PD3 are compared with each other, a phase difference in a horizontal direction (e.g., a direction of PD2↔PD3 that is shown as X direction in FIG. 3) can be detected.

In the implementation as shown in FIG. 3, all unit pixels (PXs) may be used as pixels for phase difference detection. In some implementations, only some unit pixels located at preset positions within the pixel array 100 may be used as pixels for phase difference detection. In some implementations including the present implementation as shown in FIG. 3, all unit pixels located in the pixel array 100 may be used as pixels for phase difference detection.

In each unit pixel (PX), adjacent photoelectric conversion elements (PD1˜PD3) may be connected to each other through an overflow path (OFP). In some implementations, since each unit pixel (PX) includes three photoelectric conversion elements (PD1˜PD3), the size (capacity) of each of the photoelectric conversion elements (PD1˜PD3) is very small compared to the case where only one photoelectric conversion element is formed in the unit pixel (PX).

As described above, since the capacity of each of the photoelectric conversion elements (PD1˜PD3) is small, there are very high possibilities that photocharges generated by the photoelectric conversion elements (PD1˜PD3) overflow into other unit pixels. In order to prevent or avoid the overflow between the pixels, an overflow path may be formed to interconnect adjacent photoelectric conversion elements (PD1˜PD3) within each unit pixel (PX). As a result, when photocharges more than a certain level are generated in the photoelectric conversion elements (PD1˜PD3), such photocharges generated more than the certain level can overflow into the adjacent photoelectric conversion elements within the same unit pixel. Therefore, photocharges overflowing from any one of photoelectric conversion element (PD1˜PD3) may move to other photoelectric conversion elements (PD1˜PD3) within the same unit pixel (PX) without moving to other unit pixels (PXs). This overflow path (OFP) may include impurities of the same type (e.g., N-type impurities) as the photoelectric conversion elements (PD1˜PD3).

Inter-pixel isolation structures (ISO1, ISO1′) may be formed between adjacent unit pixels (PXs) to physically isolate the unit pixels (PXs) from each other. Each of the inter-pixel isolation structures (ISO1, ISO1′) may include a trench isolation structure. For example, each of the inter-pixel isolation structures (ISO1, ISO1′) may include a Back Deep Trench Isolation (BDTI) structure or a Front Deep Trench Isolation (FDTI) structure.

In each unit pixel (PX), an inner-pixel isolation structure ISO2 may be formed between the adjacent photoelectric conversion elements (PD1˜PD3) and between the inter-pixel isolation structure ISO1 and the photoelectric conversion elements (PD1˜PD3). The inner-pixel isolation structure may include a junction isolation structure doped with impurities (e.g., P-type impurities) of a type opposite to that of the photoelectric conversion elements (PD1˜PD3) on the substrate.

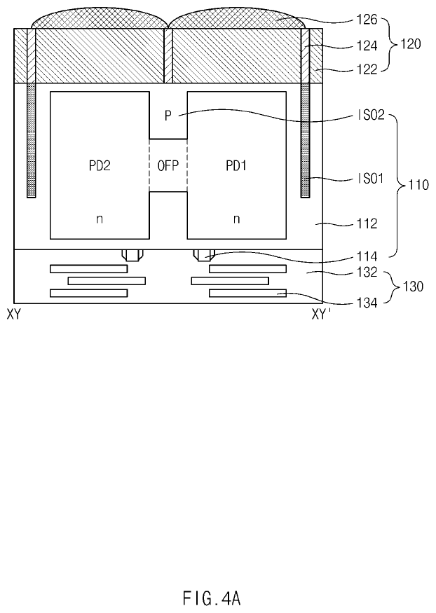

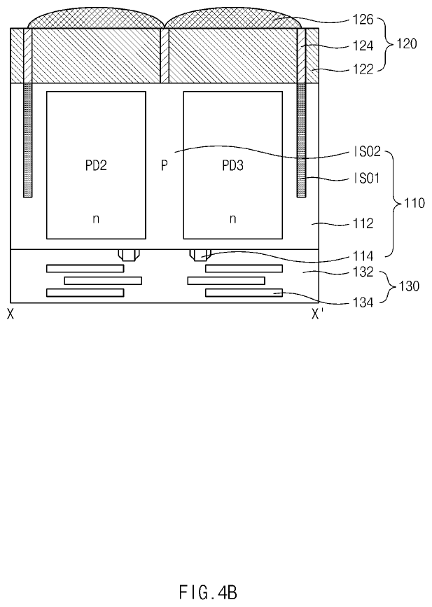

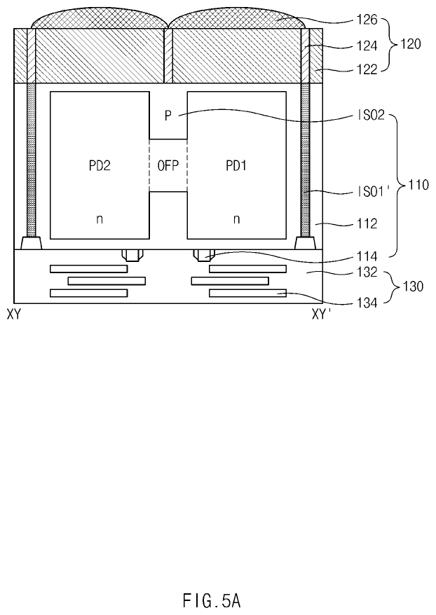

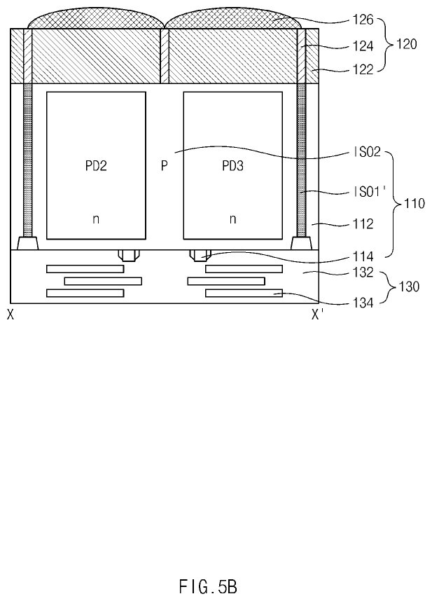

FIG. 4A is a cross-sectional view illustrating an example of a pixel structure taken along the line XY-XY′ shown in FIG. 2 based on an embodiment of the disclosed technology, and FIG. 4B is a cross-sectional view illustrating an example of a pixel structure taken along the line X-X′ shown in FIG. 2 based on an embodiment of the disclosed technology. FIG. 5A is a cross-sectional view illustrating an example of a pixel structure taken along the line XY-XY′ shown in FIG. 2 based on another embodiment of the disclosed technology, and FIG. 5B is a cross-sectional view illustrating an example of a pixel structure taken along the line X-X′ shown in FIG. 2 based on another embodiment of the disclosed technology.

Referring to FIGS. 4A, 4B, 5A, and 5B, a pixel array 100 may include a substrate layer 110, a light reception layer 120, and an interconnect layer 130.

The substrate layer 110 may include a substrate 112, pixel transistors 114, photoelectric conversion elements (PD1˜PD3), an overflow path (OFP), an inter-pixel isolation structure ISO1, and an inner-pixel isolation structure ISO2.

The substrate 112 may include a semiconductor substrate including a monocrystalline silicon material. The substrate 112 may include P-type impurities. The substrate 112 may include a first surface and a second surface facing or opposite to the first surface. In this case, the first surface may be in contact with the light reception layer 120, and may represent a surface upon which light is incident from the outside through the light reception layer 120.

The pixel transistors 114 may be formed over the second surface of the substrate 112. The pixel transistors 114 may operate in response to a control signal from the row driver 200 and output sub-pixel signals corresponding to photocharges generated by the photoelectric conversion elements (PD1˜PD3). The pixel transistors 114 may include a transfer transistor configured to transmit the photocharges generated by the photoelectric conversion elements (PD1˜PD3) to a floating diffusion node, a reset transistor configured to reset a floating diffusion node, a source follower transistor configured to generate and output a signal corresponding to the amount of charges of the floating diffusion node, and a selection transistor configured to selectively transmit an output signal of the source follower transistor to the output buffer.

The photoelectric conversion elements (PD1˜PD3) may generate photocharges through photoelectric conversion of the incident light. The photoelectric conversion elements (PD1˜PD3) may include N-type impurities. Each of the photoelectric conversion elements (PD1˜PD3) may be located at a corner region of the unit pixel (PX) formed in a triangular structure.

The overflow path (OFP) may interconnect adjacent photoelectric conversion elements (PD1˜PD3) within each unit pixel (PX). The overflow path (OFP) may be a path that allows photocharges generated by the photoelectric conversion elements (PD1˜PD3) to flow into the adjacent photoelectric conversion elements (PD1˜PD3). The overflow path (OFP) may include the same type of impurities as the photoelectric conversion elements (PD1˜PD3). The overflow path (OFP) may be formed at a higher position than the bottom surface of the photoelectric conversion elements (PD1˜PD3). For example, the bottom surface of the overflow path (OFP) may be located higher than the bottom surface of the photoelectric conversion elements (PD1˜PD3).

As the bottom surface of the overflow path (OFP) is located higher than the bottom surface of the photoelectric conversion elements (PD1˜PD3), there may occur a time difference between a start time point of an integration time during which the incident light is photoelectrically converted and integrated into the photoelectric conversion elements and an overflow time point at which the photocharges overflow. The image sensing device based on some implementations of the disclosed technology may detect a phase difference through comparison between the amounts of charges (e.g., the magnitudes of sub-pixel signals) generated by the photoelectric conversion elements (PD1˜PD3) during the time difference.

Referring to FIG. 4A, a top surface of the overflow path (OFP) may be located lower than the top surfaces of the photoelectric conversion elements (PD1˜PD3). However, other implementations are also possible. In some other implementations, the top surface of the overflow path (OFP) may be located at the same level as the top surfaces of the photoelectric conversion elements (PD1˜PD3).

The inter-pixel isolation structures (ISO1, ISO1′) may be located between the adjacent unit pixels (PXs) and within the substrate 112 to physically separate the unit pixels (PXs) from each other. Each of the inter-pixel isolation structures (ISO1, ISO1′) may include a trench isolation structure in which an insulation material is buried in a trench which is etched in the substrate 112. For example, as shown in FIG. 4A, the inter-pixel isolation structure ISO1 may include a back deep trench isolation (BDTI) structure formed to a predetermined depth that does not penetrate the substrate 112 from the first surface of the substrate 112. Alternatively, as shown in FIG. 5A, the inter-pixel isolation structure (ISO1′) may include a front deep trench isolation (FDTI) structure formed to penetrate the substrate 112 from the second surface of the substrate 112.

The inner-pixel isolation structure (ISO2) may be located between the photoelectric conversion elements (PD1˜PD3) and within each unit pixel (PX). The inner-pixel isolation structure ISO2 may include a junction isolation structure including impurities (e.g., P-type impurities) of a type opposite to that of the photoelectric conversion elements (PD1˜PD3). In the region where the overflow path (OFP) is formed, the inner-pixel isolation structure (ISO2) may be formed above and below the overflow path (OFP). The inner-pixel isolation structure (ISO2) may also be formed between the photoelectric conversion elements (PD1˜PD3) and the inter-pixel isolation structures (ISO1, ISO1′).

The light reception layer 120 may be formed over the first surface of the substrate 112. The light reception layer 120 may include a color filter layer 122, a grid structure 124, and microlenses 126.

The color filter layer 122 may include color filters that filter visible light from among incident light received through the microlenses 126. For example, the color filter layer 122 may include a plurality of red color filters, a plurality of green color filters, and a plurality of blue color filters. Each red color filter may transmit red visible light. Each green color filter may transmit green visible light. Each blue color filter may transmit blue visible light. In each unit pixel (PX), color filters of the same color may be formed to be separated for each of the photoelectric conversion elements (PD1˜PD3).

The grid structure 124 may be disposed between color filters to prevent crosstalk between the color filters. The grid structure 124 may be located not only between color filters of different colors from among the adjacent unit pixels (PXs), but also between color filters of the same color in each unit pixel (PX). The grid structure 124 may include at least one of metal or air.

The microlenses 126 may converge incident light, and may transmit the converged light to the corresponding photoelectric conversion elements (PD1˜PD3). For example, the microlenses 126 may be disposed over the photoelectric conversion elements (PD1˜PD3) in one-to-one correspondence with the photoelectric conversion elements (PD1˜PD3), and may converge the incident light onto the corresponding photoelectric conversion elements (PD1˜PD3).

The interconnect layer 130 may be disposed over the second surface of the substrate 112. The interconnect layer 130 may include an insulation layer 132 and conductive lines 134.

The insulation layer 132 may include an insulation material located between the pixel transistors 114, conductive lines 134, and contacts (not shown).

The conductive lines 134 may be connected to the pixel transistors 114, and may thus transmit signals output from the pixel transistors 114 or signals for controlling the operation of the pixel transistors 114.

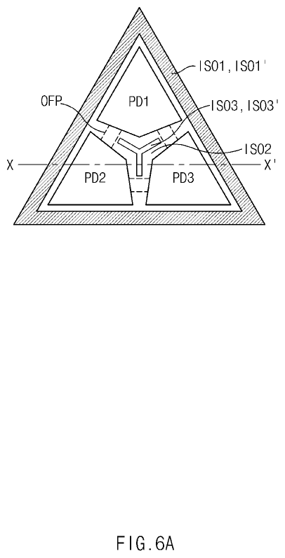

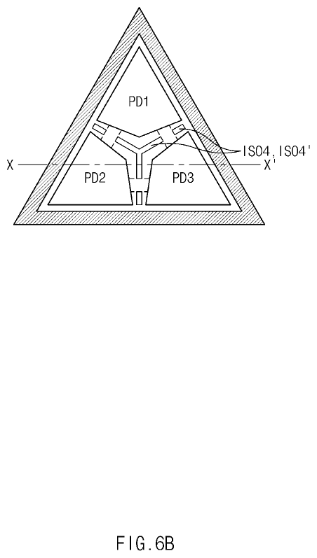

FIGS. 6A and 6B are schematic diagrams illustrating examples of inner-pixel isolation structures based on another embodiment of the disclosed technology.

Referring to FIG. 6A, the inner-pixel isolation structure may include a structure in which trench isolation structures (ISO3, ISO3′) are additionally formed in the junction isolation structure (ISO2). Each of the trench isolation structures (ISO3, ISO3′) may be formed in a three-way intersection shape extending in three directions (i.e., directions toward overflow paths OFPs) from the center of the unit pixel (PX) when viewed in a plane. For example, each of the trench isolation structures (ISO3, ISO3′) may be formed in a center region surrounded by the overflow paths (OFP) within the junction isolation structure (ISO2) disposed between the photoelectric conversion elements (PD1˜PD3). Each of the trench isolation structures (ISO3, ISO3′) may include a BDTI or FDTI structure.

Referring to FIG. 6B, the trench isolation structures (ISO4, ISO4′) may be formed entirely in a region disposed between the photoelectric conversion elements (PD1˜PD3), except for a region where the overflow paths OFPs are formed. This trench isolation structures (ISO4, ISO4′) may also include a BDTI or FDTI structure.

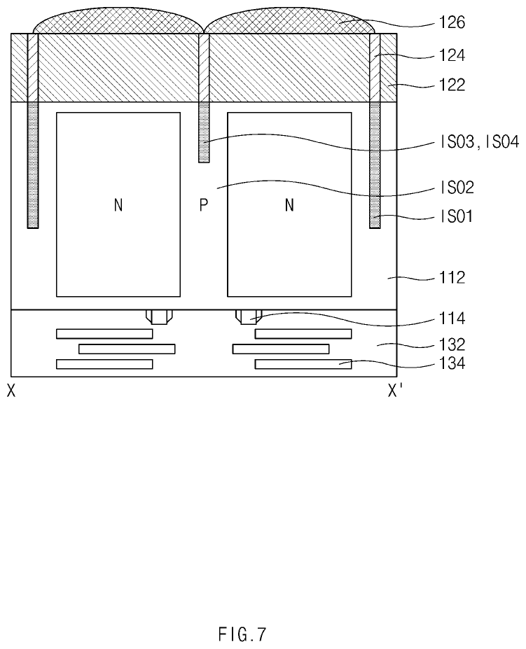

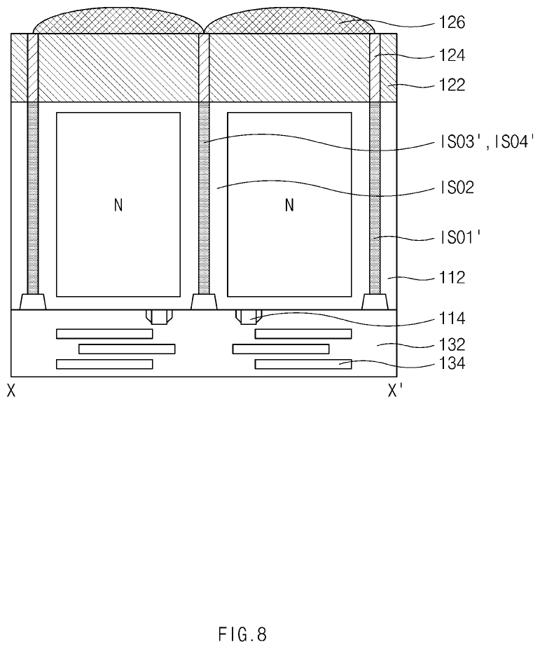

FIG. 7 is a cross-sectional view illustrating an example of the pixel structure taken along the line X-X′ shown in FIGS. 6A and 6B based on an embodiment of the disclosed technology. FIG. 8 is a cross-sectional view illustrating an example of the pixel structure taken along the line X-X′ shown in FIGS. 6A and 6B based on another embodiment of the disclosed technology.

In the embodiments of FIGS. 7 and 8, the same reference numerals are given to the same components as those in FIGS. 4A, 4B, 5A, and 5B, and as such redundant description thereof will herein be omitted for brevity.

Referring to FIG. 7, each of the trench isolation structures (ISO3, ISO4) may include the same BDTI structure as the inter-pixel isolation structure (ISO1). The trench isolation structures (ISO3, ISO4) may be formed of the same material as the inter-pixel isolation structure (ISO1). However, each of the isolation structures (ISO3, ISO4) may be formed with a shorter length (i.e., a smaller depth) than the inter-pixel isolation structure (ISO1).

Referring to FIG. 8, each of the trench isolation structures (ISO3′, ISO4′) may include an FDTI structure in the same manner as the inter-pixel isolation structure (ISO1′). The trench isolation structures (ISO3′, ISO4′) may be formed of the same material as the inter-pixel isolation structure (ISO1′). The isolation structures (ISO3′, ISO4′) may be formed to penetrate the substrate 112 in the same manner as the inter-pixel isolation structure (ISO1′).

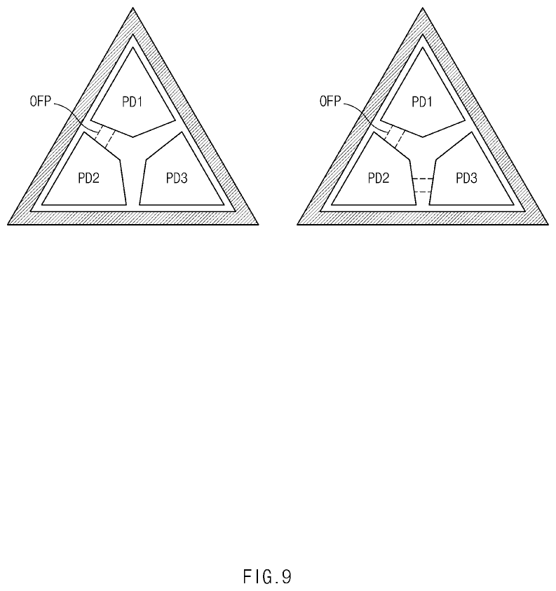

FIG. 9 is a schematic diagram illustrating examples of planar structures of a unit pixel based on another embodiment of the disclosed technology.

Referring to FIG. 9, each of the unit pixels (PXs) may selectively include only one or two overflow paths (OFPs). For example, the overflow path (OFP) may connect photoelectric conversion elements to each other in only one of the X direction, XY direction, and −XY direction (see FIG. 3), or may connect photoelectric conversion elements to each other in only two directions.

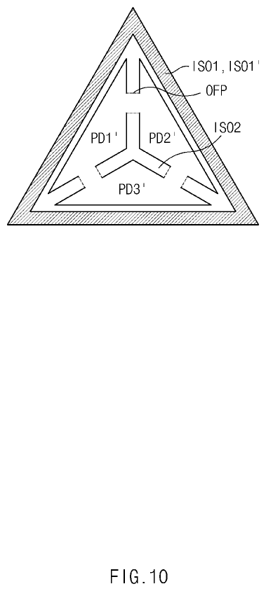

FIG. 10 is a schematic diagram illustrating an example of a planar structure of a unit pixel based on another embodiment of the disclosed technology.

Referring to FIG. 10, the unit pixel (PX) may include a plurality of photoelectric conversion elements (PD1′˜PD3′). Compared to the embodiment of FIG. 2, the embodiment of FIG. 10 differs from the embodiment of FIG. 2 in terms of positions of the photoelectric conversion elements formed in each unit pixel. For example, as can be seen from FIG. 10, three photoelectric conversion elements (PD1′˜PD3′) may be disposed in regions respectively adjacent to three sides of a triangle in one-to-one correspondence with the three sides of the triangle. While each of the photoelectric conversion elements (PD1 to PD3) in FIG. 2 is disposed to have regions located adjacent to different sides of the unit pixel, the photoelectric conversion elements (PD′1 to PD′3) is respectively located adjacent to three sides of the unit pixel.

The photoelectric conversion elements (PD1′˜PD3′) may be connected to each other through overflow paths (OFPs). Although only three overflow paths (OFPs) are illustrated in FIG. 10, the scope or spirit of the disclosed technology is not limited thereto, and it should be noted that only one or two overflow paths (OFPs) can also be selectively formed as shown in FIG. 9.

Although the inner-pixel isolation structure disposed between the photoelectric conversion elements (PD1′˜PD3′) shown in FIG. 10 is formed only with the junction isolation structure (ISO2), the embodiment of FIG. 10 may include a structure in which the junction isolation structure ISO2 is combined with the trench isolation structures (ISO3, ISO3′, ISO4, ISO4′) as shown in FIGS. 6A and 6B.

As is apparent from the above description, the image sensing device based on some implementations of the disclosed technology can improve phase-difference detection characteristics while minimizing image distortion by improving a pixel structure.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device, comprising:
a semiconductor substrate;
unit pixels supported by the semiconductor substrate to detect light incident to the unit pixels and to convert detected light into pixel signals, respectively; and
an inter-pixel isolation structure disposed between adjacent unit pixels to physically isolate the adjacent unit pixels from each other,
wherein each unit pixel is structured to include
(1) photoelectric conversion elements producing photocharge for generation of a pixel signal of each unit pixel in response to incident light detected by the unit pixel,
(2) an inner-pixel isolation structure disposed between adjacent photoelectric conversion elements within the unit pixel, and
(3) at least one overflow path configured to interconnect the photoelectric conversion elements within the unit pixel, and
wherein each unit pixel is shaped in a triangular shape when viewed in a plane.

2. The image sensing device according to claim 1, wherein:
the photoelectric conversion elements within each unit pixel are disposed in regions respectively adjacent to corners of the triangular shape in one-to-one correspondence with the corners of the triangular shape.

3. The image sensing device according to claim 1, wherein:
the photoelectric conversion elements within each unit pixel are disposed in regions respectively adjacent to sides of the triangular shape in one-to-one correspondence with the sides of the triangular shape.

4. The image sensing device according to claim 1, wherein:
the inter-pixel isolation structure includes a trench isolation structure.

5. The image sensing device according to claim 1, wherein the inner-pixel isolation structure includes:
a junction isolation structure that includes doped impurities of a doping type that is different from a doping type of doped impurities included in the photoelectric conversion elements.

6. The image sensing device according to claim 5, wherein the inner-pixel isolation structure further includes:
a trench isolation structure disposed in a center region of each unit pixel and within the junction isolation structure.

7. The image sensing device according to claim 6, wherein:
the trench isolation structure includes a portion that has a shorter length than a length of the inter-pixel isolation structure in a vertical direction.

8. The image sensing device according to claim 6, wherein:
the trench isolation structure includes a three-way intersection structure extending in three directions from a center portion of each unit pixel.

9. The image sensing device according to claim 1, wherein the photoelectric conversion elements in each unit pixel include:
a first photoelectric conversion element;
a second photoelectric conversion element disposed adjacent to the first photoelectric conversion element in a first diagonal direction; and
a third photoelectric conversion element disposed adjacent to the first photoelectric conversion element in a second diagonal direction intersecting the first diagonal direction, and disposed adjacent to the second photoelectric conversion element in a first direction intersecting the first diagonal direction and the second diagonal direction.

10. The image sensing device according to claim 9, wherein the at least one overflow path includes:
a first overflow path structured to interconnect the first photoelectric conversion element and the second photoelectric conversion element;
a second overflow path structured to interconnect the first photoelectric conversion element and the third photoelectric conversion element; and
a third overflow path structured to interconnect the second photoelectric conversion element and the third photoelectric conversion element.

11. The image sensing device according to claim 10, wherein the inner-pixel isolation structure includes:
a junction isolation structure that includes doped impurities of a doping type that is different from a doping type of doped impurities included in the photoelectric conversion elements, and
wherein the doped impurities included in the junction isolation structure are located in a region other than a region where the first to third overflow paths are formed.

12. The image sensing device according to claim 11, wherein the inner-pixel isolation structure further includes:
a trench isolation structure disposed in a region surrounded by the first to third overflow paths and within the junction isolation structure.

13. The image sensing device according to claim 1, wherein:
the at least one overflow path is located higher than a bottom surface of the photoelectric conversion elements.

14. An image sensing device, comprising:
a plurality of unit pixels consecutively arranged in a first direction and a second direction intersecting the first direction, each unit pixel exhibiting a triangular shape when viewed in a plane and configured to produce photocharge in response to incident light; and
a first isolation structure disposed between adjacent unit pixels and configured to isolate the adjacent unit pixels from each other,
wherein each of the plurality of unit pixels includes:
a first photoelectric conversion element that converts light into photocharge;
a second photoelectric conversion element that converts light into photocharge and is disposed adjacent to the first photoelectric conversion element in a first diagonal direction; and
a third photoelectric conversion element that converts light into photocharge and is disposed adjacent to the first photoelectric conversion element in a second diagonal direction intersecting the first diagonal direction, and disposed adjacent to the second photoelectric conversion element in a first direction intersecting the first diagonal direction and the second diagonal direction.

15. The image sensing device according to claim 14, further comprising:
at least one overflow path configured to interconnect at least two photoelectric conversion elements from among the first to third photoelectric conversion elements in at least one direction from among the first diagonal direction, the second diagonal direction, and the first direction.

16. The image sensing device according to claim 15, wherein the at least one overflow path includes:
a first overflow path interconnecting the first photoelectric conversion element and the second photoelectric conversion element;
a second overflow path interconnecting the first photoelectric conversion element and the third photoelectric conversion element; and
a third overflow path interconnecting the second photoelectric conversion element and the third photoelectric conversion element.

17. The image sensing device according to claim 14, wherein:
the first to third photoelectric conversion elements are disposed in regions respectively adjacent to three corners of the triangular shape in one-to-one correspondence with the three corners of the triangular shape.

18. The image sensing device according to claim 14, wherein:
the first to third photoelectric conversion elements are disposed in regions respectively adjacent to three sides of the triangular shape in one-to-one correspondence with the three sides of the triangular shape.

19. The image sensing device according to claim 14, further comprising:
a second isolation structure disposed between the first to third photoelectric conversion elements within each unit pixel.

20. An image sensing device comprising:
a semiconductor substrate;
an inter-pixel isolation structure disposed between adjacent unit pixels within the semiconductor substrate;
a plurality of photoelectric conversion elements disposed in the unit pixels within the semiconductor substrate, respectively;
an inner-pixel isolation structure disposed between adjacent photoelectric conversion elements within the unit pixel; and
at least one overflow path configured to interconnect the photoelectric conversion elements within the unit pixel,
wherein each of the unit pixels is formed in a triangular shape when viewed in a plane.
